(19) United States
(12) Patent Application Publication
(10) Pub. No.: US 2017/0006699 A1
(43) Pub. Date: Jan. 5, 2017

(54) MULTILAYER CIRCUIT BOARD, SEMICONDUCTOR APPARATUS, AND METHOD OF MANUFACTURING MULTILAYER CIRCUIT BOARD

(71) Applicant: FUJITSU LIMITED, Kawasaki-shi (JP)

(72) Inventors: Daisuke Mizutani, Sagamihara (JP); Tetsuro Yamada, Kawasaki (JP); Naoki Nakamura, Hachioji (JP); KENICHIRO ABE, Dong Nai Province (VN); Naohito MOTOOKA, Nagano (JP)

(73) Assignee: FUJITSU LIMITED, Kawasaki-shi (JP)

(21) Appl. No.: 15/264,819

(22) Filed: Sep. 14, 2016

Related U.S. Application Data
(63) Continuation of application No. PCT/JP2014/057867, filed on Mar. 20, 2014.

(51) Int. Cl. H05K 1/02; H05K 3/40; H05K 3/46; H05K 1/18; H05K 1/11

(52) U.S. Cl. CPC H05K 1/0237; H05K 1/181; H05K 1/113; H05K 3/4614; H05K 3/4007; H05K 3/4038; H05K 1/0298

(57) ABSTRACT

A multilayer circuit board with a laminated structure includes an outermost insulating layer provided as an uppermost or bottom layer of the multilayer circuit board and formed of a composite material containing a glass fiber; and a multilayer interconnect lamination provided as an adjacent layer next to the outermost insulating layer, the multilayer interconnect lamination having an interconnect provided in an insulating resin layer that does not contain a glass fiber, and an interlayer via electrically connected to the interconnect.

CROSS-REFERENCE TO RELATED APPLICATIONS

This application is a continuation application filed under 35 U.S.C. 111(a) and claims benefit under 35 U.S.C. 120 and 365(c) of PCT International Application No. PCT/JP2014/057867 filed on Mar. 20, 2014 and designating the United States, which application is incorporated herein by reference in its entirety.

### FIELD

The embodiments discussed herein relate to a multilayer circuit board, a semiconductor apparatus, and a method of manufacturing a multilayer circuit board.

### BACKGROUND

In a semiconductor device mounting structure, semiconductor chips or packages are mounted on a multilayer printed circuit board (PCB) and electrical connections are provided between chips or packages typically by interconnections formed on the surface of and/or inside the multilayer circuit board. Multilayer circuit boards are industrially manufactured by a lamination process, alternately stacking double-sided copper clad laminates with prescribed interconnect or wiring patterns and uncured or semi-cured insulation films, followed by vacuum hot press onto the stacked structure. Then through-holes are formed in the laminated structure, which through-holes are filled with a conductive material by metal plating to produce via-contacts.

A technique of reducing high-frequency noise is proposed, by bonding a polyimide film with a ground pattern or a power source pattern onto the outermost surfaces (i.e., the top face and the bottom face) of the multilayer circuit board. See, for example, Patent Document 1 listed below. Another known technique is to bond single-sided copper clad polyimide films onto the top and back surfaces of a rigid glass epoxy double-sided copper clad laminates using an adhesive sheet. See, for example, Patent Document 2 listed below. However, when a composite-material clad laminate is bonded using an adhesive to a flexible circuit layer, such as copper-coated polyimide, that does not contain glass fiber fabric, the bonded layers are likely to separate or delaminate from each other at the bonded interface due to differences in coefficients of thermal expansion or temperature-dependency of modulus of elasticity.

Still another technique for improving the adhesiveness is to form through-holes in advance in a flexible polyimide interconnect laminate having a copper (Cu) interconnect pattern of differential pair transmission lines, and filling the through-holes with a composite-material insulating resin during a lamination process. See, for example, Patent Document 3 listed below. However, forming through-holes in a flexible interconnect laminate applied to multilayer lamination processes will prevent the degree of freedom in designing interconnect patterns. Besides, an extra step for filling the through-holes with a composite material is required in the multilayer lamination process, which step also prevents the degree of freedom in designing a layered structure of a multilayer circuit board.

### LIST OF PRIOR ART DOCUMENT

Patent Document 1: Japan Patent Application Laid-open Publication No. 2003-174265

Patent Document 2: Japan Patent Application Laid-open Publication No. H5-41580

Patent Document 3: Japan Patent Application Laid-open Publication No. 2013-131526

### SUMMARY

In one aspect of the invention, a multilayer circuit board with a laminated structure is provided, which multilayer circuit board includes
an outermost insulating layer provided as an uppermost or bottom layer of the multilayer circuit board and formed of a composite material containing a glass fiber; and
a multilayer interconnect lamination provided as an adjacent layer next to the outermost insulating layer, the multilayer interconnect lamination having an interconnect provided in an insulating resin layer that does not contain a glass fiber, and an interlayer via electrically connected to the interconnect.

The object and advantages of the invention will be realized and attained by means of the elements and combinations particularly pointed out in the claims. It is to be understood that both the foregoing general description and the following detailed description are exemplary and explanatory and are not restrictive to the invention as claimed.

### BRIEF DESCRIPTION OF DRAWINGS

FIG. 1A illustrates a fabrication process of a three-layer interconnect lamination used in a multilayer circuit board according to an embodiment;

FIG. 1B illustrates a fabrication process of a three-layer interconnect lamination used in a multilayer circuit board according to the embodiment;

FIG. 1C illustrates a fabrication process of a three-layer interconnect lamination used in a multilayer circuit board according to the embodiment;

FIG. 2A illustrates a fabrication process of a three-layer interconnect lamination used in a multilayer circuit board according to the embodiment;

FIG. 2B illustrates a fabrication process of a three-layer interconnect lamination used in a multilayer circuit board according to the embodiment;

FIG. 3A illustrates a fabrication process of a three-layer interconnect lamination used in a multilayer circuit board according to the embodiment;

FIG. 3B illustrates a fabrication process of a three-layer interconnect lamination used in a multilayer circuit board according to the embodiment;

FIG. 3C illustrates a fabrication process of a three-layer interconnect lamination used in a multilayer circuit board according to the embodiment;

FIG. 4 illustrated a multilayer circuit board acquired by a lamination process according to the embodiment, compared with a hypothetical multilayer circuit board with a conventional structure;

FIG. 5 illustrates a relationship between laminating pressure applied to polyimide during a fabrication process of the three-layer interconnect lamination and pressure of collective lamination for multilayer circuit board (or printed circuit board);

FIG. 6A illustrates a fabrication process of a multilayer circuit board using the three-layer interconnect lamination;

FIG. 6B illustrates a fabrication process of a multilayer circuit board using the three-layer interconnect lamination;

FIG. 6C illustrates a fabrication process of a multilayer circuit board using the three-layer interconnect lamination;

FIG. 7A illustrates a fabrication process of a multilayer circuit board using the three-layer interconnect lamination, continued from FIG. 6C;

FIG. 7B illustrates a fabrication process of a multilayer circuit board using the three-layer interconnect lamination;

FIG. 7C illustrates a fabrication process of a multilayer circuit board using the three-layer interconnect lamination;

FIG. 8 illustrates a multilayer circuit board according to an embodiment;

FIG. 9 illustrates a multilayer circuit board according to another embodiment; and

FIG. 10 illustrates an example of a semiconductor apparatus using the multilayer circuit board of the embodiment.

### DESCRIPTION OF EMBODIMENTS

Insulating materials such as insulating bases of double-sided copper clad laminate or prepregs used in multilayer circuit boards are made of a composite material with glass fiber fabric impregnated with a thermosetting resin. As signal transmission frequencies increase, it becomes difficult for a differential transmission scheme using a pair of signal lines to tolerate or absorb a variation in transmission delay time caused by an uneven density distribution of glass fiber fabric in the circuitry aspect. Not only differential transmission lines, but also high-frequency signal transmission lines are susceptible to variation in transmission speed due to difference in dielectric constant or relative permittivity in the same product.

It may be conceived to use an expensive insulating material superior in high-frequency transmission characteristic for a layer with high-speed signal interconnects. However, in collective lamination processes, it is desired to use the same insulating material throughout a multilayer lamination stack from the viewpoint of manufacturability and reliability of circuit boards. If the entire structure of lamination is made of an expensive insulating material, which material is demanded only for a certain layer with specific type of interconnects, the production cost will increase.

To solve this technical problem, the embodiment of the invention provides a structure and a technique for reducing a variation in signal transmission delay time caused by variation in dielectric constant or relative permittivity in a multilayer circuit board fabricated by a lamination process. More specifically, in the embodiment, a layer with a specific type of interconnects such as high-frequency signal lines or a high-speed differential pair transmission line susceptible to influence of variation in dielectric constant is formed of an insulating resin film that does not contain glass fiber fabric. For example, a multilayer interconnect lamination (e.g., three-layer interconnect lamination) is formed of an insulating resin film without containing glass fiber fabric. This multilayer interconnect lamination not containing glass fiber fabric (which lamination may be referred to as a “flexible multilayer interconnect lamination”) is then laminated together with other layers using composite materials at once. Because the flexible multilayer interconnect lamination with specific type of interconnect patterns does not contain glass fiber fabric, variation in transmission delay time due to difference in density, namely, difference in relative permittivity of the glass fiber fabric can be prevented.

One example of an insulating resin film without containing glass fiber fabric is a polyimide film. Polyimide has a coefficient of thermal expansion similar to that of copper (Cu) interconnects, and glass transition does not occur in the range of operation temperature of multilayer circuit boards. Accordingly, the thermal tolerance of multilayer circuit boards can be improved.

In a preferred example, the lamination pressure during fabrication of a flexible multilayer interconnect lamination is set to 1.5 to 3 times greater, more preferably 2.0 to 2.3 times greater than the pressure of collective lamination applied when assembling a multilayer circuit board. Under this condition, warping of the flexible multilayer interconnect lamination can be prevented when subjected to collective lamination together with other layers, and dimensional precision of the multilayer circuit board fabricated by lamination can be guaranteed.

In a preferred example, an interlayer via with a closed end, such as a blind via, is formed in advance in the flexible multilayer interconnect lamination. Through the collective lamination process, a specific type of interconnect pattern of the flexible multilayer interconnect lamination is electrically connected to a surface electrode of the multilayer circuit board by the interlayer via. This arrangement simplifies electrical connection between the surface electrode and the specific type of built-in interconnect of the multilayer circuit board.

As has been described earlier, before reaching the structure and the process of the embodiment, it may be conceived not to use glass fiber fabric such as glass cloth to exclude or reduce adverse influence of glass fiber fabric. However, a multilayer circuit board without using glass fiber fabric is short of mechanical strength for supporting or having electronic components mounted. It is difficult for such a circuit board to be applied to a large-sized PCB of several tens centimeter squared with twenty or more layers. Glass fiber fabric contributes to improvement of dimensional stability of PCBs and is a suitable material for a board on which minute electronic components are mounted at high density. From the viewpoint of manufacturing efficiency, it is also preferred to use a conventional lamination process of laminating stacked layers containing glass fiber fabrics as it is.

In the embodiment, a flexible multilayer interconnect lamination with a specific type of interconnect patterns are assembled into a multilayer circuit board by an ordinary lamination process.

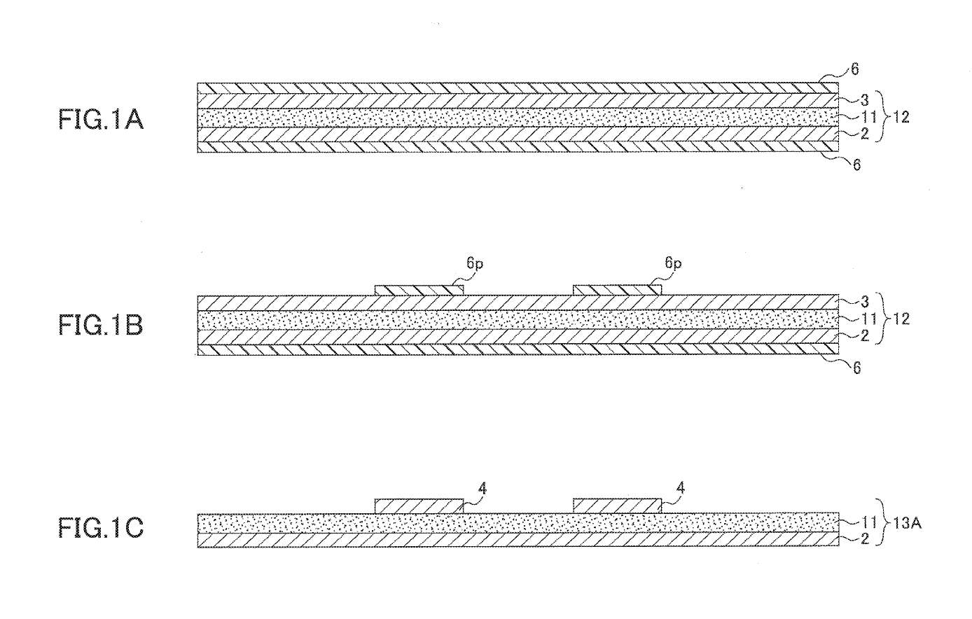

FIG. 1A through FIG. 3C illustrate a fabrication process of a multilayer interconnect lamination used in a multilayer circuit board according to the embodiment. In this example, a three-layer interconnect lamination that includes three levels of interconnections.

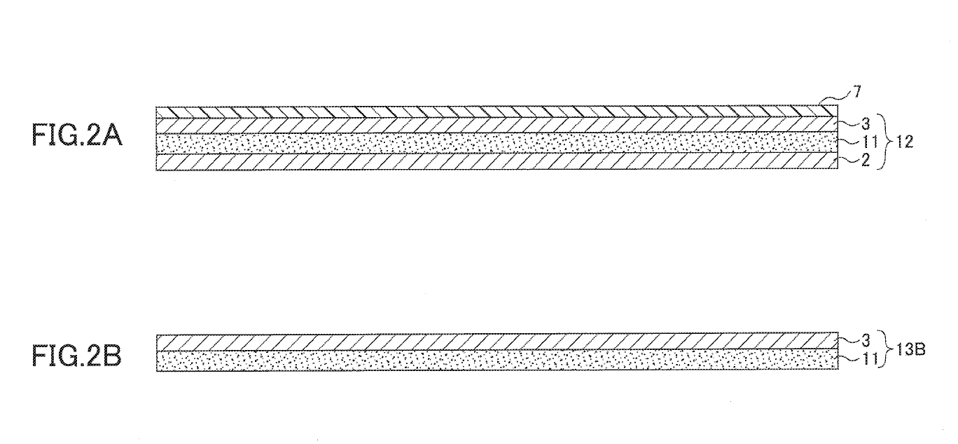

First, in FIG. 1A, a double-sided copper clad lamination 12 with copper foils 2 and 3 provided on respective faces of an insulating layer 11 is prepared. Photoresist layers 6 are deposited onto the copper foils 2 and 3, respectively. The insulating layer 11 is, for example, a resin layer without containing glass fiber fabric. In this example, “UPILEX (registered trademark)” manufactured by Ube Industries, Ltd., which is one kind of polyimide film, is used as the insulating layer 11. The thickness of the insulating layer 11 is not limited, and in this example, a 50-micron thick film is used. In FIG. 1B, exposure and development are performed on the photoresist layer 6 on one side of the lamination to form a photoresist mask 6p with a prescribed pattern corresponding to a desired interconnect pattern. In FIG. 1C, the copper foil 3 is etched into a prescribed pattern, removing unnecessary portions of the photoresist 6 using the photoresist mask 6p, and then the photoresist mask 6p is removed. Thus, a core material 13A with interconnect patterns 4 formed on one side of the insulating layer 11 is acquired. The interconnect patterns 4 are, for example, differential lines for transmitting a differential pair of signals, or high-frequency signal lines. Simultaneously or sequentially, another core material 13B is prepared as illustrated in FIG. 2A and FIG. 2B.

In FIG. 2A, a double-sided copper clad lamination 12 with copper foils 2 and 3 provided on both faces of an insulating layer 11 is prepared as in FIG. 1A. A photoresist layer 7 is deposited onto either one of the copper foils 2 and 3 (in this example, onto the copper foil 3). In FIG. 2B, the copper foil 2 on the other side is removed by etching using the photoresist layer 7 as a mask. This, the core material 13B with the copper foil 3 provided on one side of the insulating layer 11 is acquired. This core material 13 may be called a single-sided copper clad core material.

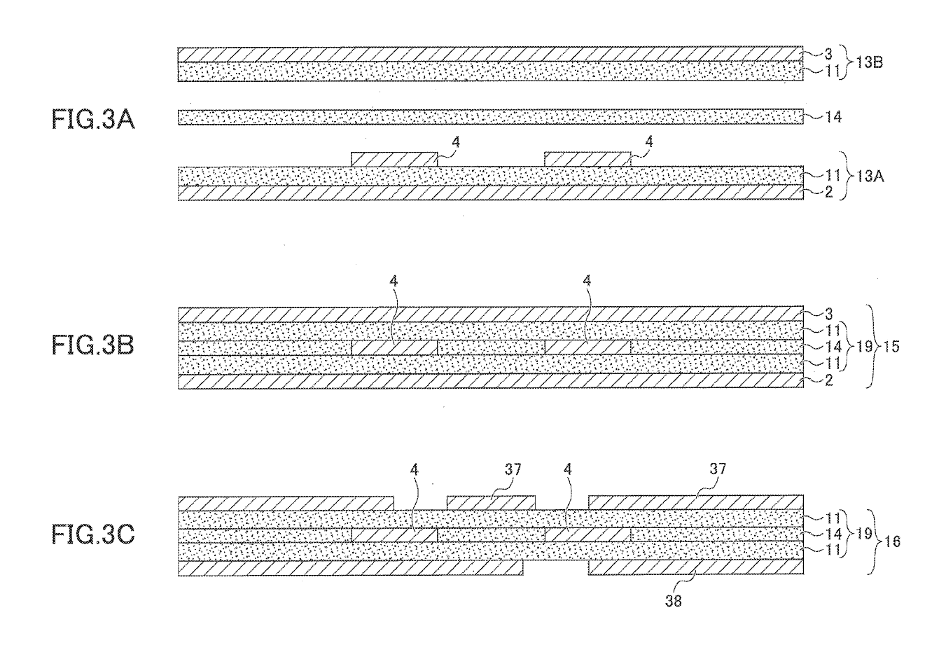

In FIG. 3A and FIG. 3B, the core materials 13A and 13B are put together to form a three-layer interconnect lamination. In FIG. 3A, the core material 13A and the core material 13B are stacked with an adhesive layer 14 between them such that the insulating layer 11 of the single-sided copper clad core material 13B faces the interconnect patterns 4 and the insulating layer 11 of the core material 13A. The adhesive layer 14 is, for example, an adhesive sheet with an modulus of elasticity less than one fifth of that of the polyimide insulating layer 11. With a smaller modulus of elasticity, the film is more deformable following external stress and more easily absorbs internal stress.

In FIG. 3B, vacuum pressing is performed on the stack of the core material 13A, the adhesive layer 14, and the core material 13B for 30 minutes under the conditions of a pressure of 6 MPa and a temperature of 180° C. to acquire a three-layer interconnect lamination 15. The three-layer interconnect lamination 15 has three levels of metal layers, that is, the cooper foil 3, the copper foil 2, and a built-in interconnect layer 19. The built-in interconnect layer 19 has the interconnect patterns 4 surrounded by the insulating layers 11 bonded by the adhesive layer 14. The polyimide resin used as the insulating layer 11 is a material whose glass transition temperature is outside the temperature range of the subsequently applied vacuum press lamination process. Besides, polyimide has a coefficient of thermal expansion similar or close to that of copper used in the interconnect patterns 4.

In FIG. 3C, the copper foil 3 and/or the copper foil 2 of the three-layer interconnect lamination 15 are/is patterned into desired interconnect patterns as necessary. In this example, interconnect patterns 37 are formed on one side of the built-in interconnect layer 19, and interconnect patterns 38 are formed on the other side of the built-in interconnect layer 19. Thus, a patterned three-layer interconnect lamination 16 is acquired.

Neither the three-layer interconnect lamination 16 nor 15 contains glass fiber fabric in the insulating layer 11. Because the polyimide insulating layer 11 and the interconnect pattern 4 have the similar coefficient of thermal expansion, the three-layer interconnect lamination 16 (or 15) can be regarded as a single layer in the aspect of thermal characteristics.

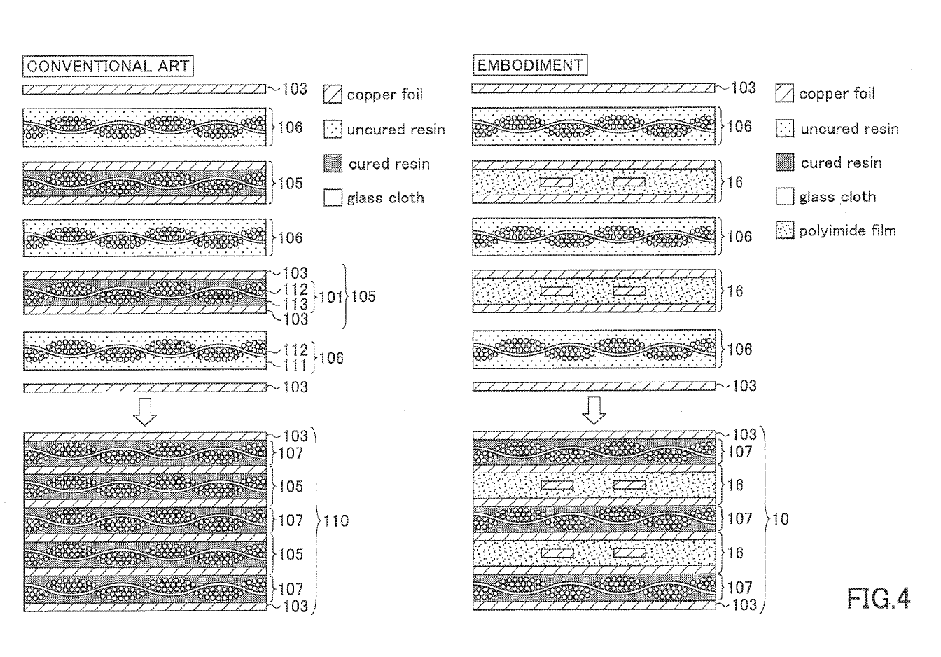

FIG. 4 on the right-hand side illustrates a lamination process using the three-layer interconnect lamination 15 (or 16) of the embodiment, compared with a conventional multilayer circuit board fabricated by a lamination process depicted on the left-hand side.

In the conventional structure on the left-hand side, the core materials 105 with copper foils 103 patterned into interconnects and prepregs 106 are stacked alternately, and the layered stack is laminated all together, with copper foils 103 placed on the top and bottom surface (as the outermost layers) of the stack, by a vacuum hot press lamination process. The insulating layer 101 of the core material 105 and the prepreg 106 are formed of a composite material containing glass fiber fabric 112.

By the lamination process, the uncured (or semi-cured) resin 111 of the prepreg 106 melts and hardens, and the prepreg 106 becomes an insulating layer 107 of a cured resin, whereby a conventional multilayer circuit board 110 is obtained. The insulating layer 101 of the core material 105 assembled into the multilayer circuit board 110 is also formed of a cured resin 113 containing glass fiber fabric 112. Accordingly, the interconnect patterns of the conventional multilayer circuit board 110 are sandwiched between the insulating layers 101 and 107 that both contain glass fiber fabrics. The dielectric constant or the relative permittivity of the insulating layers 101 and 107 varies depending on the density of the glass fiber fabric 112. When a high-speed differential pair that does not allow signal transmission delay difference or a high frequency signal line is used, the operation reliability of the multilayer circuit board is degraded.

In contrast, with the structure of the embodiment on the right-hand side, the three-layer interconnect lamination 16 without containing glass fiber fabric and the repreg 106 with glass fiber fabrics impregnated with uncured resin are alternately stacked. Then, the layered stack is laminated all together, with copper foils 103 placed on the top and bottom surface (as the outermost layers) of the stack, by vacuum press. This lamination process may be referred to as “collective lamination”. By the lamination process, the uncured (or semi-cured) resin 111 of the prepreg 106 melts and hardens, and the prepreg 106 becomes an insulating layer 107, whereby a multilayer circuit board 10 is obtained. In the multilayer circuit board 10, the three-layer interconnect lamination 16 without containing glass fiber fabric and the insulating layer 107 containing glass fiber fabric are arranged alternately. The insulating layer 107 covered directly with the outermost copper foil 103, which insulating layer 107 may be referred to as the “outermost insulating layer 107”, is made of a composite material such as a glass cloth impregnated with epoxy resin, and it has a rigidity suitable for laser processing. The three-layer interconnect lamination 16 is positioned adjacent to the outermost insulating layer 107.

The three-layer interconnect lamination 16 has interconnect patterns 4 formed in the polyimide insulating layer 11 with even or uniform distribution of dielectric constant (see FIG. 3B). Even when the interconnect pattern 4 is a high-speed differential pair transmission line or a high frequency signal line, adverse influence due to variation in dielectric constant can be prevented. Besides, the rigidity of a glass base material can be effectively used as in the ordinary lamination process. Even if the dimensions of the multilayer circuit board 10 increases, semiconductor devices (or electronic components) can be mounted at high density in a stable manner.

The coefficient of thermal expansion of polyimide used for the insulating layer 11 is similar to that of copper, and polyimide exhibits the same thermal behavior as copper in terms of the glass transition temperature outside the range of the operation temperature of the multilayer circuit board 10. These features can prevent internal stress from being generated during the lamination process or use of the multilayer circuit board 10 due to temperature change. Delamination between films of the multilayer (e.g., three-layer) interconnect lamination 16 can also be prevented.

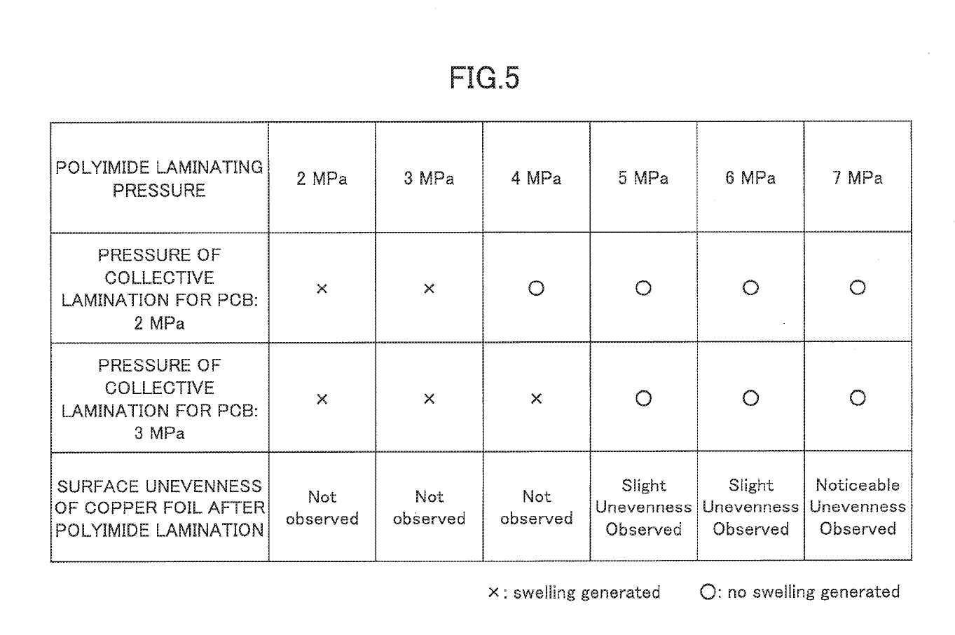

FIG. 5 illustrates a relationship between laminating pressure for fabricating a polyimide three-layer interconnect lamination 15 and collective lamination pressure for assembling a multilayer circuit board (or PCB) 10. Heat resistance test (or solder flow test) was performed at 260° C. for 1 minute, changing the laminating pressure of the three-layer interconnect lamination 105 and using different levels of collective lamination pressure for assembling the multilayer circuit board 10. The cross mark in the diagram represents that swelling is observed in the heat resistance test, and the circle mark represents that no swelling is observed in the heat resistance test. Swelling is undesirable because it may cause the delamination. The diagram also indicates at the bottom line the observation result of the surface unevenness in the copper foils 2 and 3 (see FIG. 3B) of the three-layer interconnect lamination 15 after the fabrication of the three-layer interconnect lamination by vacuum pressing.

The vacuum-press laminating pressure is changed from 2 MPa, 3 MPa, 4 MPa, 5 MPa, 6 MPa, and 7 MPa for fabricating samples of the three-layer interconnect lamination 15. Because the collective lamination pressure for assembling a multilayer circuit board is generally from 2 MPa to 3 MPa, multilayer circuit boards are fabricated at collective lamination pressure of 2 MPa and 3 MPa, respectively, by assembling each of the three-layer interconnect laminations 15 fabricated at different laminating pressures into a multilayer circuit board.

From the results of the thermal resistance test, it is understood that the laminating pressure (e.g., vacuum press pressure) for the three-layer interconnect lamination 15 is preferably in the range from 1.5 times to 3 times the collective lamination pressure for assembling the multilayer circuit board. When the laminating pressure of the three-layer interconnect lamination 15 is too high, the shape of the built-in interconnect pattern 4 may appear in the copper foils 2 and/or 3 at the surfaces of the three-layer interconnect lamination 15. In this case, patterning of the copper foils 2 and 3 may be adversely affected and therefore, it is better not to increase the vacuum press pressure for the three-layer interconnect lamination 15 too much over a suitable range. More preferably, the lamination pressure for the three-layer interconnect lamination 15 is twice to 2.3 times the collective lamination pressure for assembling the multilayer circuit board 10.

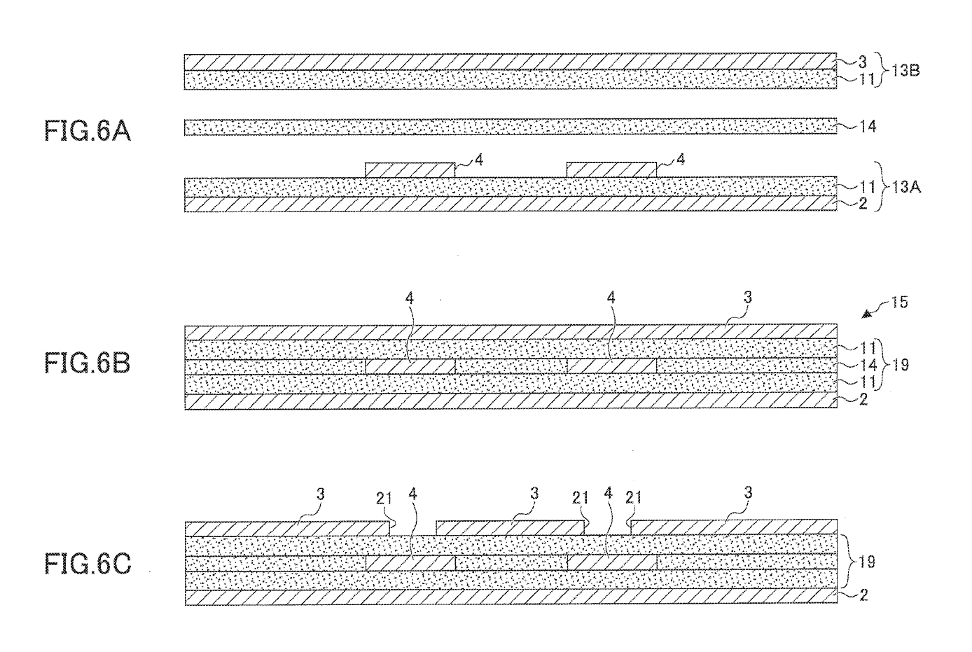

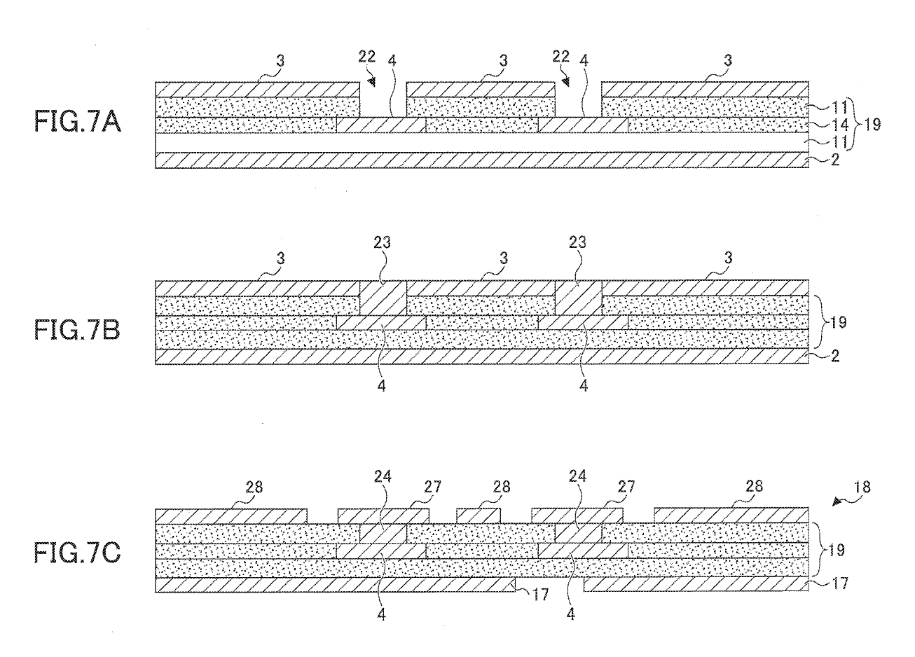

FIG. 6A to FIG. 7C illustrate a fabrication process of an interlayer via in the three-layer interconnect lamination 15. In the embodiment, prior to collective lamination of the multilayer circuit board 10, a blind via is formed in advance in the three-layer interconnect lamination 15. The “interlayer via” is a technical concept compared to a “through via”. In this example, the blind via does not pass through the three-layer interconnect lamination 15, but it is electrically connected at its bottom face to the built-in interconnect pattern 4 provided inside the three-layer interconnect lamination 15. In this regard, the blind via may be called a “bottomed via.”

In FIG. 6A, a core material 13A with interconnect patterns 4 and a core material 13B (e.g., a single-sided copper coated core) are stacked with an adhesive layer 14 between them such that the insulating layers 11 of the core materials 13A and 13B face each other. In FIG. 6B, the core material 13A, the adhesive layer 14, and the core material 13B are combined into a single form of lamination by vacuum pressing.

FIG. 6A and FIG. 6B correspond to FIG. 3A and FIG. 3B, respectively. The vacuum pressing may be performed under the same conditions as in FIG. 3A and FIG. 3B, for 30 minutes at pressure of 6 MPa and temperature of 180° C., for instance. The insulating layers 11 of the core material 13A and the core material 13B are polyimide resin layers that do not contain glass fiber fabrics. By the vacuum pressing, a three-layer interconnect lamination 15 is obtained, which lamination includes an internal interconnect layer 19 with interconnect patterns 4, the copper foil 2 on the bottom face of the internal interconnect layer 19, and the copper foil 3 on the top face of the internal interconnect layer 19.

In FIG. 6C, openings 21 are formed in the copper foil 2 or 3 on either side of the three-layer interconnect lamination 15. In this example, the openings 21 are formed in the copper foil 3 at prescribed positions by an ordinary photolithography process.

In FIG. 7A, the polyimide insulating layer 11 are etched from the openings 21 using the remaining portions of the copper foil 3 as an etching mask to form via-holes 22.

In FIG. 7B, the via-holes 22 are filled with copper (Cu) plating layers 23. The Cu plating layers 23 may be deposited by forming a seed layer over the patterned surface including the via-holes 22 by non-electrolytic plating and growing copper layers to fill the via holes 22 by electrolytic plating using the seed layer as an electrode. Then, excessive portions of the Cu plating layer are removed and the surface of the copper foil 3 is flattened and smoothed (planarized).

In FIG. 7C, a resist layer with a prescribed pattern (not illustrated in this figure) is formed over the planarized surface of the copper foil 3. The copper foil 3 is etched using the resist pattern as an etching mask and electrodes 27 and interconnect patterns 28 are formed. The electrodes 27 are electrically connected to the internal interconnect patterns 4 by the blind vias 24. The electrodes 27 may work as, for example, ground electrodes or power electrodes. Similarly, a resist pattern is formed over the copper foil 2 to etch the copper foil 2 to form interconnect patterns 17 on the other side. Thus, a three-layer interconnect lamination 18 with blind vias 24 is fabricated.

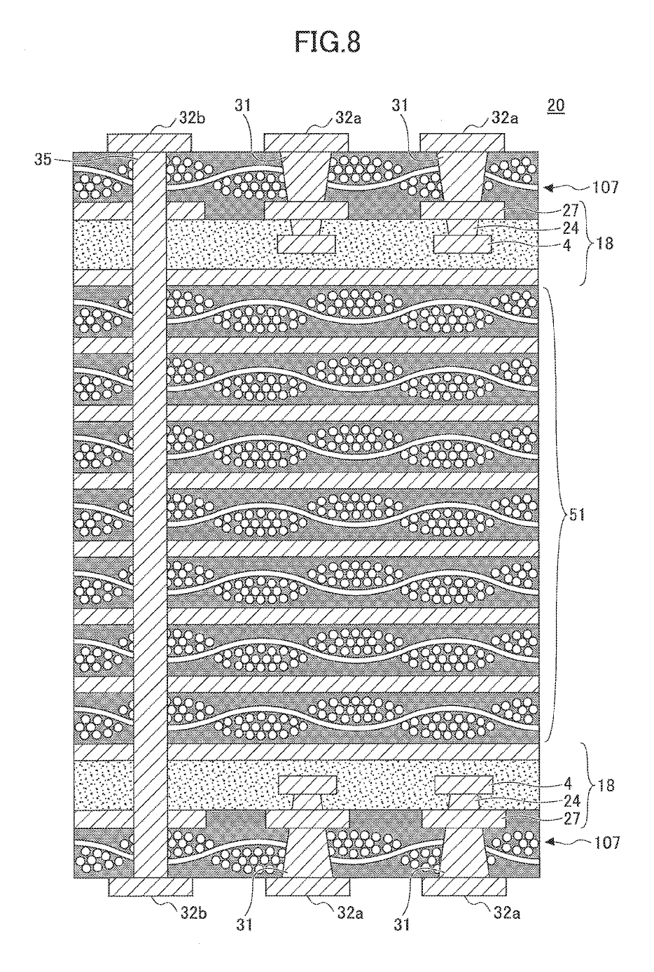

FIG. 8 is a schematic diagram of a multilayer circuit board 20 manufactured by a collective lamination process, assembling the three-layer interconnect lamination 18 of FIG. 7C into the board. In the multilayer circuit board 20, the three-layer interconnect lamination with the blind vias 24 is arranged in vicinity of or adjacent to the outermost insulating layer 107. The outermost insulating layer 107 is a composite material insulating layer containing glass fiber fabric. Surface electrodes 32a and 32b are provided on the surface of the outermost insulating layer 107.

The electrodes 32a are electrically connected to the interconnect patterns 4 built in the three-layer interconnect lamination 18 through a via plug 31 formed in the outermost insulating layer 107, the electrode 27, and the blind via 24. The electrode 32b is electrically connected to another electrode 32b formed on the reverse side by a through via 35.

The multilayer circuit board 20 may be fabricated by the following process. A layered stack 51 in which one or more composite material insulating layer(s) and one or more interconnect layer(s) are alternately stacked is prepared. The three-layer interconnect lamination 18 with blind vias 24 is placed on one of or both sides of the layered stack 51. The interconnect patterns 4 of the three-layer interconnect lamination 18 are formed in the insulating resin layer that does not contain glass fiber fabric, as already explained. Then, a copper-coated insulating layer is placed over the three-layer interconnect lamination 18 such that the electrodes 27 connected to the blind vias 24 of the three-layer interconnect lamination 18 face the copper coating (foil) of the insulating layer. The copper-coated insulating layer becomes the outermost layer.

These layers are assembled into a bulk by vacuum pressing (i.e., collective lamination). The pressure of the collective lamination is less than the laminating pressure on the three-layer interconnect lamination 18 with the blind vias 24, and is set to, for example, 3 MPa. By the vacuum pressing, uncured or semi-cured resin melts and hardens and the tracked layers are assembled into a single board. Thermal history remains in the polyimide of the three-layer interconnect lamination 18 that is assembled into the multilayer circuit board 20 by the collective lamination process. Accordingly, the polyimide layer of the multilayer circuit board 20 can be distinguished from other resin layers bonded after collective lamination (or vacuum pressing).

Then, a through-hole is formed in the assembled board at a prescribed position by laser processing. Via-holes reaching the electrodes 27 of the three-layer interconnect lamination 18 are also formed by laser processing. The through-hole and the via-holes are filled with Cu plating to form a through via 35 and via plugs 31. Then, the copper coating (foil) of the outermost insulating layer 107 is processed into a prescribed pattern to form electrodes 32a and 32b on the outermost insulating layer 107, whereby the multilayer circuit board 20 is obtained.

With this process, the outermost insulating layer 107 can be formed of a conventional composite material, and the via plugs 31 connected to the electrodes 27 of the three-layer interconnect lamination 18 can be formed from the top face of the post-lamination multilayer circuit board 20, passing through the outermost insulating layer 107. The electrodes 27 are connected to the internal interconnect patterns 4 by the blind vias 24 formed in advance in the three-layer interconnect lamination 18. Accordingly, open via stabs which may become a problem for high-speed transmission lines can be removed.

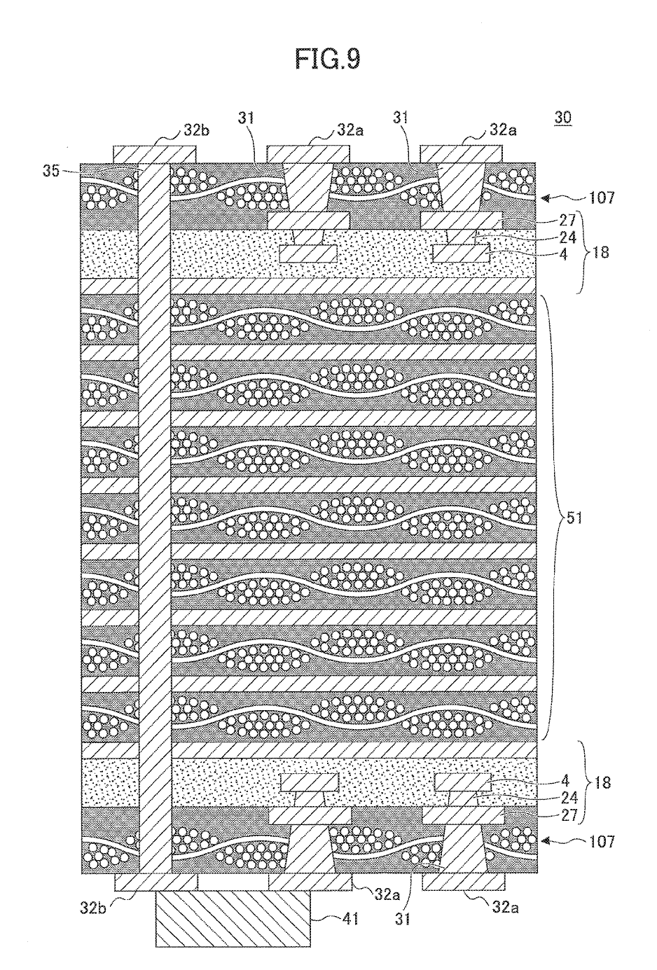

FIG. 9 is a schematic diagram of a multilayer circuit board 30, which circuit board is a modification of the structure of FIG. 8. The multilayer circuit board 30 is fabricated by the similar process as the multilayer circuit board 20 of FIG. 8, except for providing an alternate current (AC) capacitor 41.

Assuming that the top surface with the upper side electrodes 32a and 32b in the figure is used as a device/component mounting surface and that the bottom side of the figure is a back face of the multilayer circuit board 30, the electrode 32b and the electrode 32a on the back face are coupled by the AC coupling capacitor 41. The back side electrode 32b is connected to the electrode 32b on the device/component mounting surface by the through via 35. The back side electrode 32a is electrically connected to the interconnect pattern 4 (such as a high-speed differential pair) positioned in the vicinity of another outermost insulating layer provided on the back side, by a via plug 31, an electrode 27 and a blind via 24 of a back-side three-layer interconnect lamination 18. With this structure, multiple interconnect layers can be used as stubless high-speed signal transmission layers.

With either structure of FIG. 8 or FIG. 9, the through via 35 and the via plug 31 connected to the blind via 24 are formed after the collective lamination process for assembling the three-layer interconnect lamination 18 with a blind via 24 formed in advance, together with other layers of a composite material, into the multilayer circuit board. The freedom in layout design of interconnect patterns in the three-layer interconnect lamination and the freedom in designing the layered structure of the multilayer circuit board can be guaranteed.

The three-layer interconnect lamination 18 with blind vias 24 (see FIG. 7C) is fabricated easily by ordinary vacuum pressing and photolithography techniques. Because the three-layer interconnect lamination 18 does not contain glass fiber or glass fiber fabric, adverse influence on high-speed signal lines due to uneven density distribution of glass fiber fabric can be prevented. The multilayer circuit board 20 or 30 using the three-layer interconnect lamination 18 achieves stable operation in the high-frequency rage.

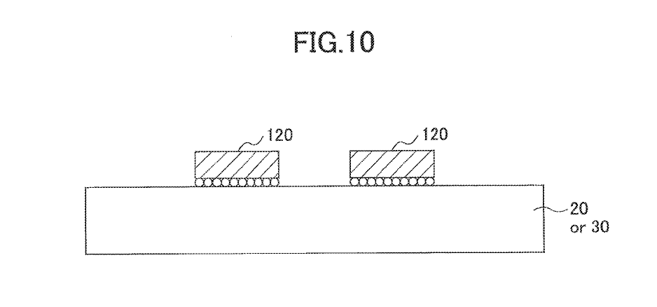

FIG. 10 illustrates a semiconductor apparatus using the multiplayer circuit board 20 or 30 illustrated in FIG. 8 or FIG. 9. By placing one or more semiconductor devices (or packages) 120 onto the device/component mounting surface of the multilayer circuit board 20 or 30, a semiconductor apparatus with high reliability in operations can be manufactured. The semiconductor device 120 may be mounted onto the electrode 32a provided on the top face of the outermost insulating layer 107 and connected to the interconnect pattern 4 (such as a differential pair) by the blind via 24.

Although in the embodiment a three-layer interconnect lamination with three conductive layers and polyimide films is used, the invention is not limited to this example. For example, a multilayer interconnect lamination with four or more conductive layers and insulating resin films that do not contain glass fibers or glass fiber fabrics may be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of superiority or inferiority of the invention. Although the embodiments of the present inventions have been described in detail, it should be understood that the various changes, substitutions, and alterations could be made hereto without departing from the spirit and scope of the invention.

What is claimed is:

1. A multilayer circuit board with a laminated structure, comprising:
an outermost insulating layer provided as an uppermost or bottom layer of the multilayer circuit board and formed of a composite material containing a glass fiber; and
a multilayer interconnect lamination provided as an adjacent layer next to the outermost insulating layer, the multilayer interconnect lamination having an interconnect provided in an insulating resin layer that does not contain a glass fiber, and a interlayer via electrically connected to the interconnect.

2. The multilayer circuit board as claimed in claim 1, further comprising:
a first surface electrode provided on a surface of the outermost insulating layer; and
a via plug provided in the outermost insulating layer,
wherein the first surface electrode is electrically connected to the interconnect by the via plug and the interlayer via.

3. The multilayer circuit board as claimed in claim 1,
wherein the interconnect provided in the insulating resin layer is a differential pair.

4. The multilayer circuit board as claimed in claim 1, wherein the insulating resin layer has a coefficient of thermal expansion similar or close to that of the interconnect.

5. The multilayer circuit board as claimed in claim 1, wherein the insulating resin layer is a polyimide layer and the interconnect is a copper interconnect.

6. The multilayer circuit board as claimed in claim 1, further comprising:
a through via that passes through the multilayer circuit board in a laminated direction; and
a second surface electrode provided on a surface of the outermost insulating layer and electrically connected to the through via.

7. A semiconductor apparatus comprising:
a multilayer circuit board having an outermost insulating layer provided as an uppermost or bottom layer of the multilayer circuit board and formed of a composite material containing a glass fiber, and a multilayer interconnect lamination provided as an adjacent layer next to the outermost insulating layer, the multilayer interconnect lamination having an interconnect provided in an insulating resin layer that does not contain a glass fiber and an interlayer via electrically connected to the interconnect; and
a semiconductor device mounted on a surface electrode provided on the outer most insulating layer of the multilayer circuit board.

8. The semiconductor apparatus as claimed in claim 7,
wherein the multilayer circuit board further has a via plug provided in the outermost insulating layer and connected to the surface electrode, and
wherein the semiconductor device is electrically connected to the interconnect by the surface electrode, the via plug and the interlayer via.

9. The semiconductor device as claimed in claim 7, further comprising:
a passive component provided onto a second surface of the multilayer circuit board on an opposite side of a semiconductor device mounting surface,
wherein the multilayer circuit board further has
a second insulating resin layer positioned at or in vicinity of the second surface, the second insulating resin layer not containing a glass fiber,
a high-speed signal line provided in the second insulating resin layer, and
a through via that passes through the multilayer circuit board in a laminated direction, and
wherein the through via and the high-speed signal line are coupled by the passive component.

10. A method of manufacturing a multilayer circuit board, comprising:
fabricating a multilayer interconnect lamination by vacuum pressing at a first pressure, the multilayer interconnect lamination having a first interconnect built in an insulating resin layer without containing a glass fiber and a second interconnect formed on at least one surface of the insulating result layer; and
combining the multilayer interconnect lamination and an insulating layer made of a composite material containing a glass fiber by a lamination process at a second pressure lower than the first pressure.

11. The method as claimed in claim 10, wherein the first pressure is equal to or greater than twice the second pressure, and equal to or less that two point three times the second pressure.

12. The method as claimed in claim 10, further comprising:
forming a interlayer via connecting the first interconnect and the second interconnect in the multilayer interconnect lamination before the lamination process.

13. The method as claimed in claim 10, further comprising:
forming a via plug in the insulating layer of the composite material by laser processing after the lamination process, the via plug being electrically connected to the first interconnect.

14. The method as claimed in claim 10, further comprising:
forming a interlayer via connecting the first interconnect and the second interconnect in the multilayer interconnect lamination before the lamination process; and
forming a via plug reaching the second interconnect in the insulating layer of the composite material, and a surface electrode connected to the via plug, thereby electrically connecting the surface electrode to the first electrode by the interlayer via.

15. The method as claimed in claim 10, further comprising:
forming a through via that passes through the multilayer circuit board by laser processing after the lamination process.

16. The method as claimed in claim 10, wherein the multilayer interconnect lamination is fabricated using an insulating resin material and an interconnect material having a similar coefficient of thermal expansion.

17. The method as claimed in claim 10, wherein in the multilayer interconnect lamination, the insulating resin layer is formed of polyimide and the first interconnect and the second interconnect are formed of copper.
